(19) United States
(12) Patent Application Publication
(10) Pub. No.: US 2014/0244195 A1
(43) Pub. Date: Aug. 28, 2014

(54) TESTING SYSTEM AND METHOD FOR VIDEO GRAPHICS ARRAY PORT

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: HAO HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/082,198

(22) Filed: Nov. 18, 2013

(30) Foreign Application Priority Data
Feb. 26, 2013 (CN) 2013100595436

(51) Int. Cl. G01R 13/22

(52) U.S. Cl. CPC G01R 13/22
USPC 702/67

(57) ABSTRACT

A VGA port testing system includes an oscilloscope and a testing device. The oscilloscope is adapted to connect to a VGA port of a motherboard to capture and detect signals output from the VGA port. The testing device is connected to the oscilloscope and adapted to automatically adjust preset parameters of the oscilloscope and create a testing report according to signal waveforms detected by the oscilloscope. The testing device further displays testing results according to the testing reports. A VGA port testing method using the VGA port testing system is also provided.

### BACKGROUND

1. Technical Field

The present disclosure relates to systems and methods for testing ports of servers, and particularly to a testing system and a method for testing Video Graphics Array (VGA) ports.

2. Description of Related Art

In computer or media systems, a VGA port is provided to couple to a display device. When testing the VGA port, a display is connected to the VGA port, the VGA port outputs a video signal to show graphics on the display, and an operator observes the display results. However, it is inconvenient for the operator to observe the display results, and the operator may read the display results incorrectly.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of a system for testing VGA port.

FIG. 2 is a flowchart of one embodiment of a method for testing VGA port using the testing system of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

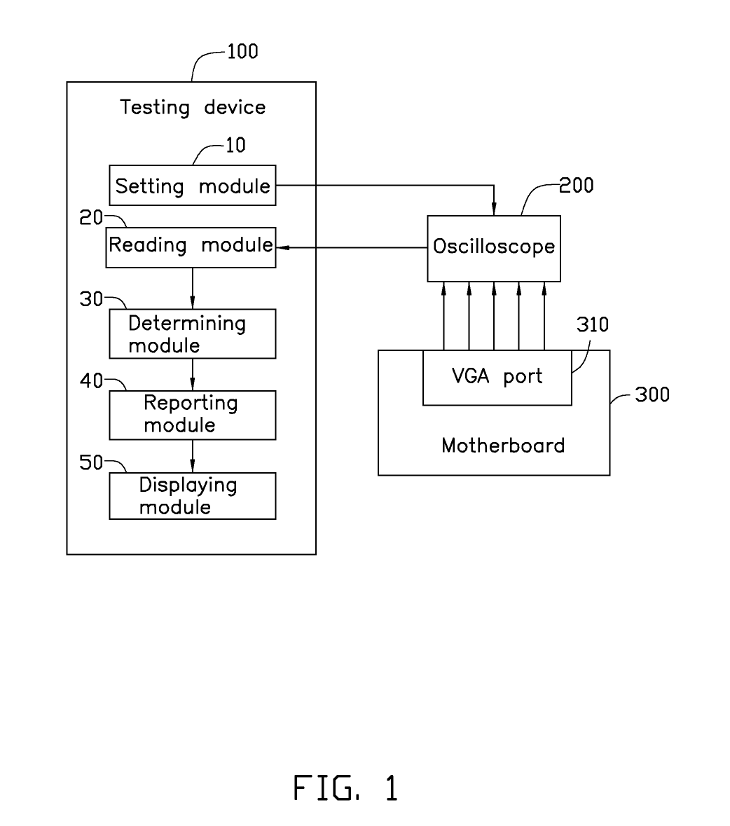

FIG. 1 shows an embodiment of a VGA port testing system for testing signals of a VGA port 310 of a motherboard 300. The testing system includes a testing device 100 and an oscilloscope 200 connected to the testing device 100.

The testing device 100 includes a setting module 10 connected to the oscilloscope 200, a reading module 20 connected to the oscilloscope 200, a determining module 30 connected to the reading module 20, a reporting module 40 connected to the determining module 30, and a displaying module 50 connected to the reporting module 40.

The VGA port 310 includes a red signal output pin R, a green signal output pin G, a blue signal output pin B, a horizontal synchronizing signal output pin Hs, and a field synchronizing signal output pin Vs. The oscilloscope 200 measures output signals outputted from the VGA port 310.

In testing, the setting module 10 presets parameters, such as a unit voltage value, a position of an origin of a coordinate system, and a triggering condition. The unit voltage value is a voltage value of each unit of the coordinate system and can be 0.1V or 1V, for example. Two same output signals output two different waveforms under different unit voltage values. The position of the origin of the coordinate system determines a starting position of the waveforms on a screen of the oscilloscope 200. The triggering condition determines a condition under which the oscilloscope 200 starts to detect signals output from the VGA port 310 and capture waveforms of the signals. In one embodiment, the oscilloscope 200 starts to detect signals output from the VGA port 310 and capture waveforms of the signals upon detecting that a signal from the oscilloscope 200 changes from a high-level to a low-level signal or changes from a low-level to a high-level signal. The reading module 20 reads data carried by the waveforms captured by the oscilloscope 200. The determining module 30 compares the data read by the reading module 20 with the preset parameters and determines whether the data conforms to the preset parameters. The reporting module 40 automatically creates a testing report, which records a name of each VGA port 310 and a plurality of data, such as amplitude and frequency, corresponding to the name. The displaying module 50 displays the testing results according to the testing report.

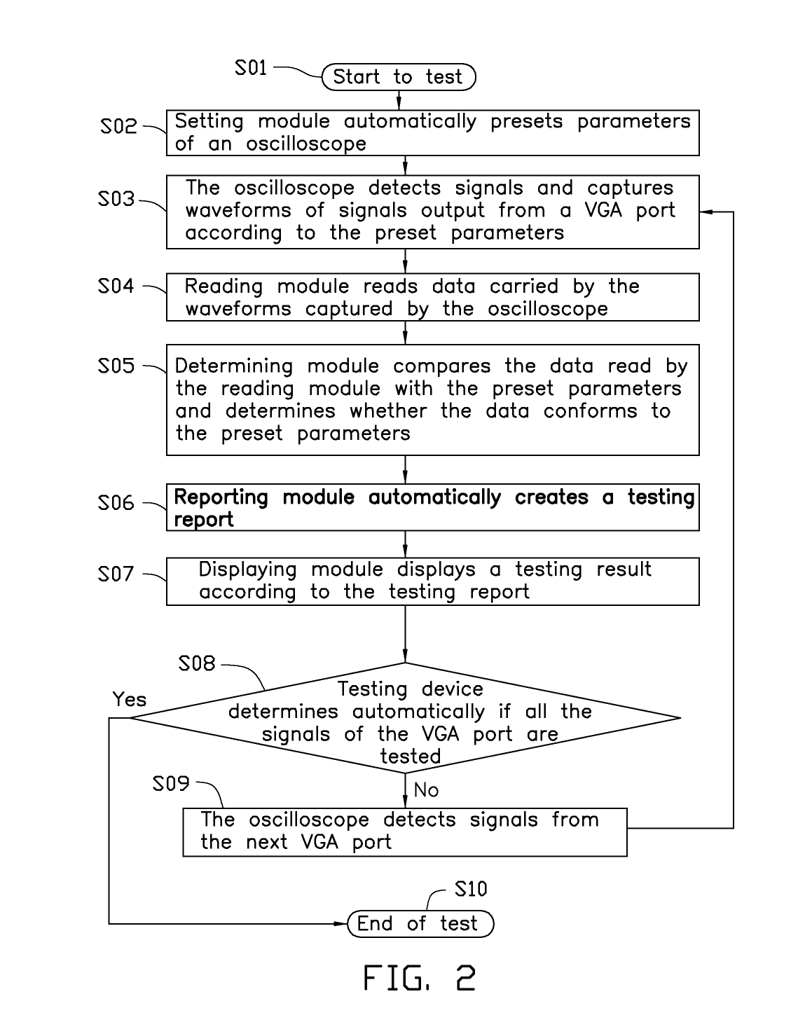

FIG. 2 shows one embodiment of a VGA port testing method.

In step S01, the test is started.

In step S02, the setting module 10 automatically presets parameters, such as a unit voltage value, a position of an origin of a coordinate system, and a triggering condition of the oscilloscope 200.

In step S03, the oscilloscope 200 detects signals and captures waveforms of the signals output from the VGA port 310 according to the preset parameters. In one embodiment, the oscilloscope 200 detects the red signal output port R, the green signal output pin G, the blue signal output pin B, the horizontal synchronizing signal output pin Hs, and the field synchronizing signal output pin Vs one-by-one.

In step S04, the reading module 20 reads data carried by the waveforms captured by the oscilloscope 200.

In step S05, the determining module 30 compares the data read by the reading module 20 with the preset parameters and determines whether the data conforms to the preset parameters. If the data conforms to the preset parameters, the waveforms are qualified. If the data does not conform to the preset parameter, the waveforms are unqualified.

In step S06, the reporting module 40 automatically creates a testing report. The testing report records a name of each VGA port 310 and a plurality of data, such as an amplitude and frequency, corresponding to the name.

In step S07, the displaying module 50 displays a testing result according to the testing report.

In step S08, the testing device 100 determines automatically if all the signals of the VGA port are tested. If so, the process is finished. If not, the process continues to step S09.

In step S09, the oscilloscope 200 detects signals from the next VGA port 310 and returns to step S03.

It is to be understood, however, that even though numerous characteristics and advantages of the embodiments have been set forth in the foregoing description, together with details of the structure and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A VGA port testing system, comprising:
an oscilloscope adapted to connect to a VGA port of a motherboard to be tested and detect signals and capture waveform of the signals output from the VGA port; and
a testing device connected to the oscilloscope;
wherein the testing device is adapted to automatically adjust preset parameters of the oscilloscope and create a testing report according to signal waveforms detected by the oscilloscope, and the testing device is further adapted to display testing results according to the testing report.

2. The VGA port testing system of claim 1, wherein the testing device comprises a setting module adapted to preset a unit voltage value, a position of an origin of a coordinates system, and a triggering condition of the oscilloscope.

3. The VGA port testing system of claim 2, wherein the testing device further comprises a reading module adapted to read data carried by the signal waveforms.

4. The VGA port testing system of claim 3, wherein the testing device further comprises a determining module adapted to compare the data with the preset parameters and determine whether the data conforms to the preset parameters.

5. The VGA port testing system of claim 1, wherein the testing device further comprises a reporting module adapted to create a testing report.

6. The VGA port testing system of claim 5, wherein the reporting module records name of each VGA port, amplitude, and frequency corresponding to the name.

7. The VGA port testing system of claim 5, wherein the testing device further comprises a displaying module adapted to display a testing result according to the testing report.

8. The VGA port testing system of claim 1, wherein the VGA port comprises a red signal output port, a green signal output port, a blue signal output port, a horizontal synchronizing signal output port, and a field synchronizing signal.

9. A VGA port testing method, comprising:
connecting an oscilloscope to a VGA port of a motherboard to be tested;
adjusting automatically preset parameters of the oscilloscope by a testing device;
detecting signals and capturing waveforms of the signals output from the VGA port;
creating a testing report according to signal waveforms captured by the oscilloscope; and;
displaying a testing result according to the testing report.

10. The VGA port testing method of claim 9, wherein the step of adjusting automatically preset parameters of the oscilloscope by the testing device comprises presetting a unit voltage value, a position of an origin of a coordinates system, and a triggering condition of the oscilloscope; and the oscilloscope captures the signal waveforms under the triggering condition.

11. The VGA port testing method of claim 10, further comprising reading data carried by the signal waveforms by a reading module before the step of creating the testing report.

12. The VGA port testing method of claim 11, further comprising comparing the data with the preset parameters and determining whether the data conforms to the preset parameters after the step of reading data carried by the signal waveforms.
